(19) United States
(12) Patent Application Publication
(10) Pub. No.: US 2011/0042126 A1
(43) Pub. Date: Feb. 24, 2011

(54) CONTACT RESISTANCE MEASUREMENT FOR RESISTANCE LINEARITY IN NANOSTRUCTURE THIN FILMS

(75) Inventors: Michael Spaid, Mountain View, CA (US); Florian Pschenitzka, San Francisco, CA (US)

Correspondence Address: SEED INTELLECTUAL PROPERTY LAW GROUP PLLC, 701 FIFTH AVE, SUITE 5400, SEATTLE, WA, 98104, US

(73) Assignee: CAMBRIOS TECHNOLOGIES CORPORATION, Sunnyvale, CA (US)

(21) Appl. No.: 12/862,548

(22) Filed: Aug. 24, 2010

Related U.S. Application Data
(60) Provisional application No. 61/274,975, filed on Aug. 24, 2009.

(51) Int. Cl. H05K 1/00; G01R 27/08

(52) U.S. Cl. 174/250; 324/691

(57) ABSTRACT

The present disclosure is directed to a transparent conductor for use in touch panel devices having a plurality of nanostructures therein that provides reliable output based on user touch or pen input. To determine if a touch panel is reliable, there is disclosed a method of measuring voltages across the transparent conductor when it is touched. These measured voltages are converted into contact resistances, which are statistically analyzed. A median contact resistance is determined based on the converted contact resistances. The remaining set of converted contact resistances are analyzed to determine if they are within acceptable limits. Acceptable limits may include most of the contact resistances falling within a range, none of the contact resistances exceeding an upper limit, and a difference in contact resistances converted for different users or pens does not exceed a maximum variability.

### CROSS-REFERENCE TO RELATED APPLICATION

This application claims the benefit under 35 U.S.C. §119(e) of U.S. Provisional Patent Application No. 61/274,975 filed Aug. 24, 2009, where this provisional application is incorporated herein by reference in its entirety.

### BACKGROUND

1. Technical Field

This disclosure is related to transparent conductors, methods of testing various physical properties of the same, and applications thereof.

2. Description of the Related Art

Transparent conductors refer to thin conductive films coated on high-transmittance surfaces or substrates. Transparent conductors may be manufactured to have surface conductivity while maintaining reasonable optical transparency. Such surface conducting transparent conductors are widely used as transparent electrodes in flat liquid crystal displays, touch panels, electroluminescent devices, and thin film photovoltaic cells, as anti-static layers and as electromagnetic wave shielding layers.

Currently, vacuum deposited metal oxides, such as indium tin oxide (ITO), are the industry standard materials to provide optically transparency and electrical conductivity to dielectric surfaces such as glass and polymeric films. However, metal oxide films are fragile and prone to damage during bending or other physical stresses. They also require elevated deposition temperatures and/or high annealing temperatures to achieve high conductivity levels. There also may be issues with the adhesion of metal oxide films to substrates that are prone to adsorbing moisture such as plastic and organic substrates, e.g. polycarbonates. Applications of metal oxide films on flexible substrates are therefore severely limited. In addition, vacuum deposition is a costly process and requires specialized equipment. Moreover, the process of vacuum deposition is not conducive to forming patterns and circuits. This typically results in the need for expensive patterning processes such as photolithography.

Conductive polymers have also been used as optically transparent electrical conductors. However, they generally have lower conductivity values and higher optical absorption (particularly at visible wavelengths) compared to the metal oxide films, and suffer from lack of chemical and long-term stability.

Accordingly, there remains a need in the art to provide transparent conductors having desirable electrical, optical and mechanical properties, in particular, transparent conductors that are adaptable to any substrates, and can be manufactured and patterned in a low-cost, high-throughput process.

### BRIEF SUMMARY

Transparent conductors based on electrically conductive nanostructures in an optically clear matrix are described. The transparent conductors are patternable and are suitable as transparent electrodes in a wide variety of devices including, without limitation, display devices (e.g., touch panels, liquid crystal displays, plasma display panels and the like), electroluminescent devices, and photovoltaic cells.

There is disclosed a transparent conductor including a substrate and at least one conductive layer on the substrate. The conductive layer may be include a plurality of metallic nanostructures and have a range of contact resistances. The range of contact resistances is between a lower percentage and an upper percentage of a median contact resistance of the conductive layer. The median contact resistance is less than a limit resistance at which the conductive layer begins to have degraded performance.

There is also disclosed a transparent conductor that includes a substrate and a conductive layer on the substrate. The conductive layer including a plurality of metallic nanostructures, and is associated with a set of contact resistances. The contact resistances fall between a lower percentage of a first median contact resistance of the conductive layer and an upper percentage of the first median contact resistance of the conductive layer.

There is also disclosed a method for determining the usability of a touch panel with a transparent conductor. The method including measuring a set of contact resistances across a surface of the transparent conductor. Determining a median contact resistance from the set of contact resistances and determining a percentage of the contact resistances from the set of contact resistances that fall within a range of resistances that surrounds the median contact resistance. If either the percentage of the contact resistances is lower than a first percentage threshold, or a contact resistance from the set of contact resistances is above a contact resistance limit, then the transparent conductor fails to fall within acceptable operating limits.

### BRIEF DESCRIPTION OF THE SEVERAL VIEWS OF THE DRAWINGS

In the drawings, identical reference numbers identify similar elements or acts. The sizes and relative positions of elements in the drawings are not necessarily drawn to scale. For example, the shapes of various elements and angles are not drawn to scale, and some of these elements are arbitrarily enlarged and positioned to improve drawing legibility. Further, the particular shapes of the elements as drawn are not intended to convey any information regarding the actual shape of the particular elements, and have been selected solely for ease of recognition in the drawings.

FIG. 1A is an illustration of a touch panel type device including a transparent conductor with two opposing conductive layers.

FIG. 1B is a magnified view of the transparent conductor from the touch panel shown in FIG. 1A.

FIG. 2 is a schematic view of the touch panel from FIG. 1A coupled to testing circuitry to measure various properties of the touch panel, particularly the transparent conductor.

FIG. 3 is a top view of the touch panel for measuring properties of the underlying transparent conductor, where test lines are traced on the surface of the transparent conductor.

FIG. 4 are graphs illustrating the measured and converted resistance values from the test shown in FIG. 3.

FIG. 5 are graphs illustrating a distribution of measured and converted resistance values from the graphs in FIG. 4.

FIG. 6 illustrates a process in which the touch panel is tested for reliability.

FIG. 7 illustrates another process in which the touch panel is tested for reliability.

### DETAILED DESCRIPTION

Certain embodiments are directed to a touch panel with a transparent conductor based on a conductive layer of nanostructures. In particular, the conductive layer includes a sparse network of metal nanostructures. In addition, the conductive layer is transparent, flexible and can include at least one surface that is conductive. It can be coated or laminated on a variety of substrates, including flexible and rigid substrates. The conductive layer can also form part of a composite structure including a matrix material and the nanostructures. The matrix material can typically impart certain chemical, mechanical and optical properties to the composite structure. Further, according to a preferred embodiment, the touch panel is a resistive touch panel.

As used herein, “conductive nanostructures” or “nanostructures” generally refer to electrically conductive nano-sized structures, at least one dimension of which is less than 500 nm, more preferably, less than 250 nm, 100 nm, 50 nm or 25 nm. Typically, the nanostructures are made of a metallic material, such as an elemental metal (e.g., transition metals) or a metal compound (e.g., metal oxide). The metallic material can also be a bimetallic material or a metal alloy, which comprises two or more types of metal. Suitable metals include, but are not limited to, silver, gold, copper, nickel, gold-plated silver, platinum and palladium.

The nanostructures can be of any shape or geometry. The morphology of a given nanostructure can be defined in a simplified fashion by its aspect ratio, which is the ratio of the length over the diameter of the nanostructure. For instance, certain nanostructures are isotropically shaped (i.e., aspect ratio=1). Typical isotropic nanostructures include nanoparticles. In preferred embodiments, the nanostructures are anisotropically shaped (i.e., aspect ratio≠1). The anisotropic nanostructure typically has a longitudinal axis along its length. Exemplary anisotropic nanostructures include nanowires, nanorods, and nanotubes, as defined herein.

The nanostructures can be solid or hollow. Solid nanostructures include, for example, nanoparticles, nanorods and nanowires. “Nanowires” typically refers to long, thin nanostructures having aspect ratios of greater than 10, preferably greater than 50, and more preferably greater than 100. Typically, the nanowires are more than 500 nm, more than 1 μm, or more than 10 μm long. “Nanorods” are typically short and wide anistropic nanostructures that have aspect ratios of no more than 10.

Hollow nanostructures include, for example, nanotubes. Typically, the nanotube has an aspect ratio (length:diameter) of greater than 10, preferably greater than 50, and more preferably greater than 100. Typically, the nanotubes are more than 500 nm, more than 1 μm, or more than 10 μm in length.

Nanostructures of higher aspect ratio (e.g., nanowires) may be favored over nanostructures of lower aspect ratio (i.e., no more than 10) because the longer the nanostructures, the fewer may be needed to achieve a target conductivity. Fewer nanostructures in a conductive film may also lead to higher optical transparency and lower haze, both parameters can be important in display technology.

### Conductive Layer and Substrate

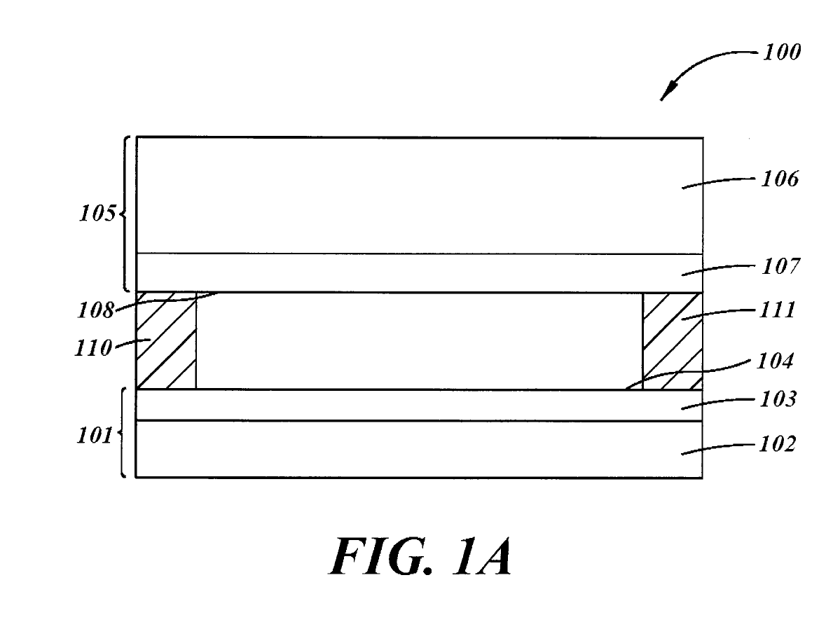

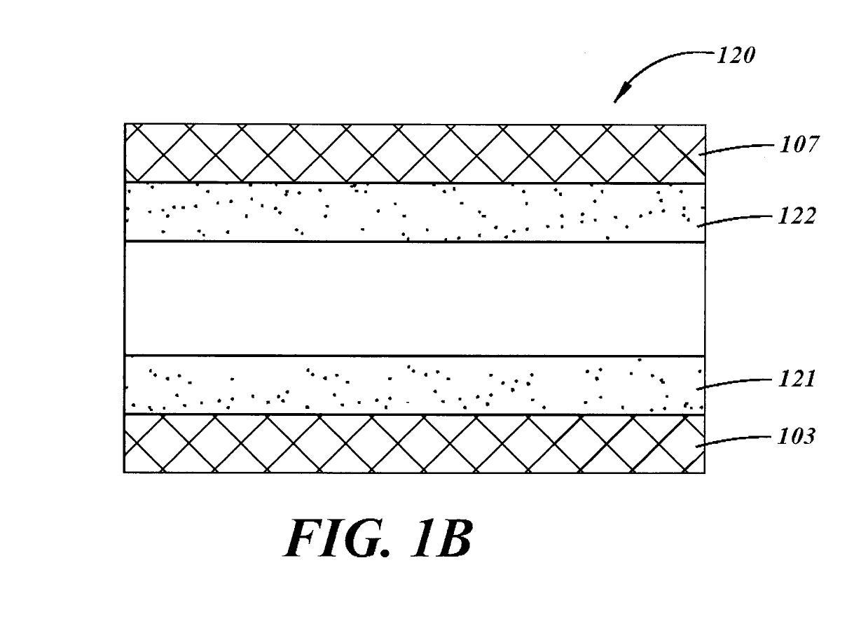

In a first embodiment, FIG. 1A shows schematically a touch panel 100, preferably a resistive touch panel or the like. The touch panel 100 includes a bottom panel 101 comprising a first substrate 102 coated or laminated with a first conductive layer 103, which has a top conductive surface 104. An upper panel 105 is positioned opposite from the bottom panel 101 and separated therefrom by adhesive enclosures 110 and 111 at respective ends of the touch panel 100. The upper panel 105 includes a second conductive layer 107 coated or laminated on a second substrate 106. The second conductive layer 107 has an inner conductive surface 108 facing the top conductive surface 104.

When a user touches the upper panel 105, the inner conductive surface 108 and the top conductive surface 104 of the bottom panel 101 come into electrical contact. Due to the electrical contact, a contact resistance is created, which causes a change in the electrostatic field. A controller (not shown) senses the change in the electrostatic field and resolves an actual touch coordinate, which information is then passed to an operating system.

As used herein, “contact resistance” generally refers to the resistance that exists between conductive surfaces of a top and bottom panel in a conductive device when the conductive surfaces form an electrical connection at a point. The “contact resistance” generally forms a part of the total resistance of a material or system in addition to the intrinsic resistance of a material. Unlike a sheet resistance, which is measured in ohms over an area, a “contact resistance” is measured in ohms.

According to this embodiment, either or both of the first and second conductive layers 103 and 107 are comprised of conductive nanowire layers, as described herein. The inner conductive surface 108 and the top conductive surface 104 each have sheet resistance in the range of about 10-1000Ω/□, more preferably, about 10-500Ω/□. Optically, the upper and bottom panels 105 and 101 have high transmission (e.g., >85%) to allow for images to transmit through.

In certain embodiments, the first and second conductive layers 103 and 107 can be further coated with a protective layer (e.g., a dielectric overcoat), which improves the durability of the transparent conductive layer. However, making electrical contact with the underlying metal nanowires may become problematic because contact resistance cannot be reliably created due to the intervening dielectric overcoat(s). In addition, even slight variations in thickness in the film overcoat may result in non-contact points on the overcoat. Thus, in these embodiments, the overcoat layers are embedded with nano-sized conductive particles to create reliable electrical contacts and to improve contact resistance.

FIG. 1B schematically shows two opposing conductive layers 103 and 107, as first shown in FIG. 1A, but with respective overcoats, i.e., films 121 and 122. More specifically, the first conductive layer 103 is coated with a first film 121 and the second conductive layer 107 is coated with a second film 122. The first and second films 121 and 122 are embedded with nano-sized conductive particles. The presence of the nano-sized conductive particles in the films 121 and 122 increases their surface conductivity and provides electrical connection between the underlying nanowire-filled conductive layers 103 and 107.

As an illustrative example, FIG. 1B shows a transparent conductor 120 used in a touch panel 100. The transparent conductor 120 has a first conductive layer 103 and a second conductive layer 107. The conductive layers 103 and 107 may comprise a plurality of nanostructures. The nanostructures form a conductive network and increase conductivity of the transparent conductor 120. In an alternative embodiment, one or more of the conductive layers 103 and 107 may be formed on a substrate 102 or 106 as shown in FIG. 1A, with the plurality of nanostructures embedded therein. The embedded nanostructures may form structures such as matrices as seen in the conductive layers 103 and 107 of FIG. 1B. The matrices may further comprise embedded nanowires.

In another embodiment, the films 121 and 122 may be applied, through conventional thin-film application techniques, to the conductive layers 103 and 107 and may be referred to as a network layer of nanostructures that provide the conductive media of the transparent conductor 120. Since conductivity is achieved by electrical charge percolating from one nanostructure to another, sufficient nanostructures must be present in the conductive layers 103 and 107 to reach an electrical percolation threshold and become conductive with or without the films 121 and 122. The surface conductivity of the conductive layers 103 and 107 is inversely proportional to their sheet resistance, sometimes referred to as sheet resistance, which can be measured by known methods in the art.

Likewise, when the matrices as seen in conductive layers 103 and 107 of FIG. 1B are present, they may be filled with sufficient nanostructures to become conductive. As used herein, “threshold loading level” refers to a percentage of the nanostructures by weight after loading of the conductive layers 103 and 107 at which the conductive layers 103 and 107 have a sheet resistance of no more than about 10⁶ ohm/square (or Ω/□). More typically, the sheet resistance is no more than 10⁵Ω/□, no more than 10⁴Ω/□, no more than 1,000Ω/□, no more than 500Ω/□, or no more than 100Ω/□. The threshold loading level depends on factors such as the aspect ratio, the degree of alignment, degree of agglomeration and the resistivity of the nanostructures.

In certain embodiments, surface conductivity may be enhanced by incorporating a plurality of nano-sized conductive particles in films 121 and 122 that are coupled to the conductive layers 103 and 107, respectively. Advantageously, the loading level of the nano-sized conductive particles in the films 121 and 122 does not need to reach the percolation threshold to exhibit surface conductivity as the nanostructures in the matrices of conductive layers 103 and 107 do. The conductive layers 103 and 107 remain as the current-carrying medium, in which the nanostructures have reached electrical percolation level. The nano-sized conductive particles in the films 121 and 122 provide for surface conductivity as a result of their contacts with the underlying nanostructures through the thickness of the films 121 and 122.

As used herein, nano-sized conductive particles refer to conductive particles having at least one dimension that is no more than 500 nm, more typically, no more than 200 nm. Examples of suitable nano-sized conductive particles include, but are not limited to, ITO, ZnO, doped ZnO, metallic nanostructures (including those described herein), metallic nanotubes, carbon nanotubes (CNT) and the like.

In further embodiments, the films 121 and 122 may start as substrates that are subsequently embedded with nano-sized particles by known methods in the art. The substrates may be rigid or flexible. The substrates may also be clear or opaque. The term “substrate of choice” is typically used in connection with a lamination process. Suitable rigid substrates include, for example, glass, polycarbonates, acrylics, and the like. Suitable flexible substrates include, but are not limited to: polyesters (e.g., polyethylene terephthalate (PET), polyester naphthalate, and polycarbonate), polyolefins (e.g., linear, branched, and cyclic polyolefins), polyvinyls (e.g., polyvinyl chloride, polyvinylidene chloride, polyvinyl acetals, polystyrene, polyacrylates, and the like), cellulose ester bases (e.g., cellulose triacetate, cellulose acetate), polysulphones such as polyethersulphone, polyimides, silicones and other conventional polymeric films. Additional examples of suitable substrates can be found in, e.g., U.S. Pat. No. 6,975,067.

As known in the art, touch panel devices may also be made including only a single substrate having a transparent conductor and both this type of touch panel device and the two conductor type described above may include a third transparent conductor that functions as an electrostatic discharge layer. The transparent conductor described herein may be used in any of these types of touch panel devices. Additionally, nanostructure-based transparent conductors used in such devices may be patterned or any other way known in the art.

According to further embodiments, the conductive layers 103 and 107 of touch panel 100 are optically clear to allow light and image to transmit through. Currently available touch panels typically employ metal oxide conductive layers (e.g., ITO films). As noted above, ITO films are costly to fabricate and may be susceptible to cracking if used on a flexible substrate. In particular, ITO films are typically deposited on glass substrates at high temperature and in vacuo. In contrast, the transparent conductors described herein can be fabricated by high throughput methods and at low temperatures. They also allow for diverse substrates other than glass. For example, flexible and durable substrates such as plastic films can be coated with nanostructures and become surface-conductive, as may be done with films 121 and 122.

Unlike the nanostructures in the underlying matrices of the conductive layers 103 and 107, which form a conductive network above the electrical percolation threshold to ensure an in-plane conductivity (e.g., between 10-1000Ω/□ in resistivity), the conductive particles in the films 121 and 122 may be conductive without reaching the electrical percolation threshold. For example, the sheet resistance of the films 121 and 122 can be as high as 10⁸Ω/□. Even at this level, the resistivity through the films 121 and 122 is low enough for touch panel applications.

The films 121 and 122 can be formed of any of the optically clear polymeric matrix materials described herein. The thickness of the film is typically less than 2 μm or less than 1 μm. Typically, a thicker film is likely to result in a higher contact resistance. Any type of nano-sized conductive particles can be used. Examples of suitable conductive particles include, but are not limited to, ITO, ZnO, doped ZnO, metallic nanostructures, metallic nanotubes or carbon nanotubes (CNT) as described herein. The sizes of the conductive particles are typically lower than 200 nm to maintain an acceptable level of haze. More typically, they are lower than 100 nm. Because the loading level of the conductive particles is so low, their presence typically does not affect the optical transmission. On the other hand, the presence of the conductive particles may provide a certain degree of surface roughness that serves to reduce glare.

In certain embodiments, the conductive particles can be a mixture of highly conductive particles (e.g., metal nanostructures) and low-conductivity particles (e.g., ITO or ZnO powders). While the highly conductive particles may be conductive below the electrical percolation threshold, they provide a high-conductivity path over a relatively large distance. The current will be mostly transported in the highly conductive particles while the low-conductivity particles will provide the electrical connection between the nanostructures.

Advantageously, the sheet resistance of the film can be controlled in a wider range by adjusting the ratio of the highly conductive particles to low-conductivity particles. Since the highly conductive particles do not have to form a percolative network, it is expected that the resistivity of the final film will be in a more linear relationship with the underlying nanowire concentration and stable at higher sheet resistances than using the low-conductivity particles alone. The mixture of nano-sized particles can be co-deposited with a matrix material in a one-pass process. Alternatively, in a two-pass process, a nanowire layer can be deposited (without necessarily forming a percolative network) prior to depositing the overcoat layer embedded with the low-conductive particles. It is also considered that the low or no aspect ratio conductive nanoparticles can be combined in a single layer with anisotropic conductive nanoparticles.

### Testing Contact Resistance in Transparent Conductors

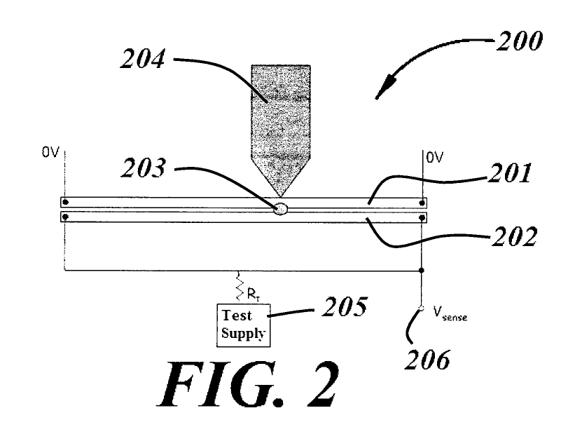

As seen in FIG. 2, there is a touch panel 200 formed from a transparent conductor similar to the transparent conductor 120 shown in FIG. 1B. The touch panel 200 has a bottom panel 101 and a top panel 105, as described herein. Due to the contact resistance sensitivities of touch panel devices as previously described, proper functioning can be ensured by performing testing on each touch panel 200.

To test the transparent conductor 120 of the touch panel 200, the bottom panel 101 is connected to a voltage testing supply 203 that supplies a supply voltage V₀. In the present embodiment, the supply voltage is set at five volts, but may be any suitable testing voltage that will not harm the underlying circuitry and touch panel materials but will allow for adequate testing of the touch panel 200. The top panel 105 is preferably set at a zero voltage level. Also, connected to the bottom panel 101 and the voltage testing supply 203, there is a resistor RT. There is also a sense terminal 204 at which a sensing voltage Vsense can be detected. The sensing voltage is used to measure a voltage caused by the bottom panel 101 and the top panel 105 coming into electrical contact at a point 201. The sensing voltage Vsense is used to calculate the contact resistances for each point of contact made between the bottom panel 101 and the top panel 105. For example, electrical contact is made at the point 201 when a user applies pressure to the top panel 105 either through use of a finger or pen 202. Examples of the pen 202 may be a stylus pen or the like. Electrical contact made at point 201 occurs when the first conductive layer 103 and the second conductive layer 107 come into contact, as previously described with regard to FIG. 1B.

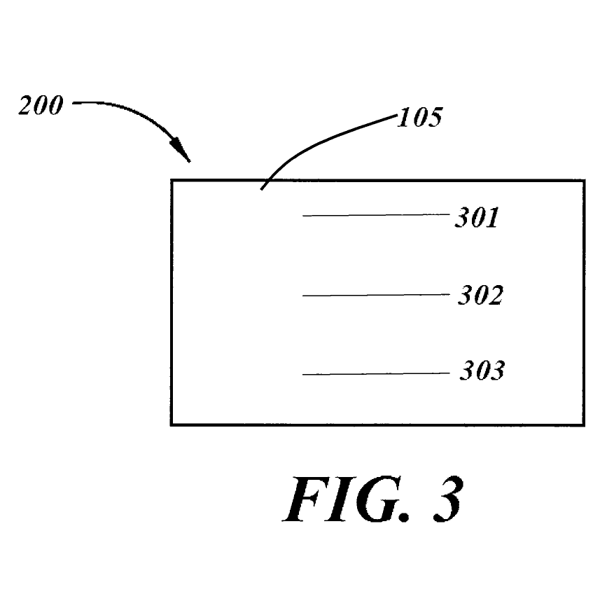

According to one embodiment of the present disclosure, there is a testing method for testing touch panels, such as the touch panel 200 shown in FIG. 2. The method creates one or more test patterns on the touch panel by the user finger or the pen 202. The test patterns preferably are made across several regions of the touch panel to obtain a set of test samples that is representative of the contact resistances across the entire surface of the touch panel. For example, in FIG. 3, a testing method according to one embodiment creates a set of stripes 301, 302, and 303 as the test patterns. It will be appreciated that the test patterns could include more or fewer test stripes, non-parallel stripes, polygons, random patterns, or any other arrangement.

During testing of the touch panel 200, the testing stripes 301, 302, and 303 are drawn along the surface of the top panel 105 as seen in FIG. 3, by either the finger of a user or the pen 202. For each testing stripe 301, 302, and 303, a set of sensing voltages Vsense is measured at the sense terminal 204. The set of sensing voltages may be recorded in a memory of a computing system (not shown). In one embodiment, each of the stripes 301, 302, and 303 is approximately 7 centimeters long. Stripes of other lengths, or different patterns, may also be used as long as an accurate and spatially varied set of measurements is made. The stripes 301, 302, and 303, or other test pattern, are preferably separated by a sufficient distance so as to obtain a meaningful sample of sensing voltages across a large enough surface of the touch panel 200. Additionally, during testing approximately 300 sensing voltage samples are taken from stripes 301, 302, and 303. However, the sample size of sensing voltages may be any size that provides for an adequate sample size to determine reliability of the touch panel 200.

Once a set of sensing voltages has been obtained, the sensing voltages are converted into a set of contact resistances. This may be done as the sensing voltages are being measured or after all sensing voltages have been measured, stored in a memory, and then retrieved for conversion into contact resistances. The contact resistances are determined based on the following resistance conversion equation:

R_{C}=V_{S}R_{T}/V_{O}−V_{S}

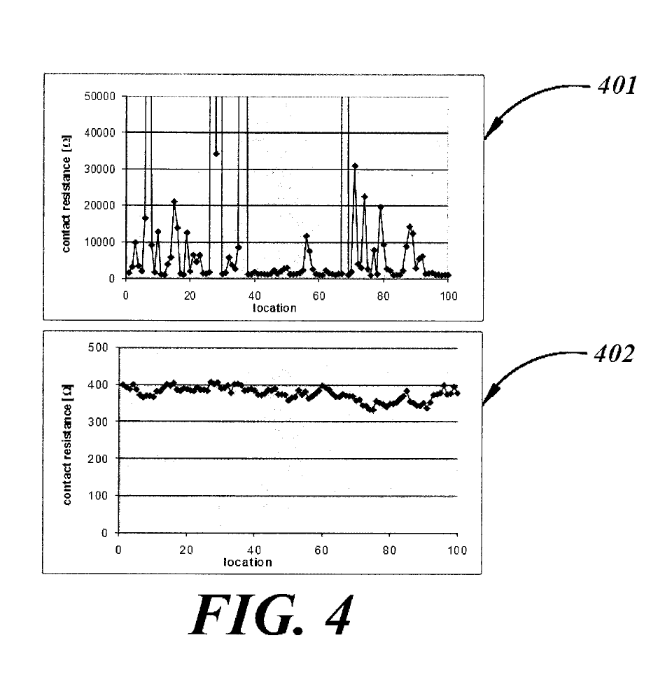

According to the above equation, a contact resistance R_{C} is determined from the sensing voltage V_{S}, the supply voltage V₀ (5 volts in this example), and a reference resistor R_{T}. The reference resistor R_{T} preferably has a value of 100 kilo-ohms (kΩ). The value of the resistor R_{T} can be any value of resistance as long as the order of magnitude of the resistor R_{T} is greater than the order of magnitude for the sheet resistances of the top and bottom panels 105 and 101 and the contact resistances. Once all of the sensing voltages V_{S} are converted into corresponding contact resistances R_{C}, they are plotted on a vertical access with their corresponding location on the horizontal axis, as shown in FIG. 4.

According to one embodiment, there are two plots 401 and 402 of contact resistances taken from two different tested touch panels as shown in FIG. 4. Plot 401 represents a set of contact resistances taken from a defective touch panel where there is large variability in the measured sensing voltages V_{S} taken across the three stripes 301, 302, and 303 as seen in FIG. 3. As seen in the plot 401, the plotted contact resistances are highly variable, with contact resistances approaching the same order of magnitude as the reference resistor R_{T}. This causes a high degree of variability in the sensing voltage V_{S}, and thus causes the output of the defective touch panel to not track the inputted shape. The result is wiggly or jagged lines on the output of the touch panel.

In contrast, the plot 402 of FIG. 4 shows a set of contact resistances converted from a second set of sensing voltages measured from a second normal-functioning touch panel. The sensing voltages measured from the second normal-functioning touch panel are measured in a similar manner as shown for the touch panel 200 shown in FIG. 3 using the three stripes 301, 302, and 303. As before, any suitable test pattern may be used as long as an adequate set of test samples may be obtained to give a large enough set of sensed voltages. In a preferred embodiment, the set of test values is 300, but can be higher or lower, but preferably not so low as to give a statistically insignificant set of data. As shown in the plot 402, there is very little variation in the plotted contact resistances over a variety of locations. Thus, there is very little variation among the sensing voltages measured. The end result would be smooth tracking of the input seen as output on the screen of the touch panel 200.

As described above with reference to FIGS. 1-4, it is desirable for each touch panel to track the user's input as closely and smoothly as possible. It is advantageous for each touch panel to have not only a minimal variance in contact resistances across the entire surface of the touch panel, but also each contact resistance should be much smaller in magnitude than at least the reference resistance R_{T}. That is to say, when testing a touch panel device, it is desirable for the measured sensing voltages to remain small and thus the contact resistances to remain small and within a relatively narrow distribution range.

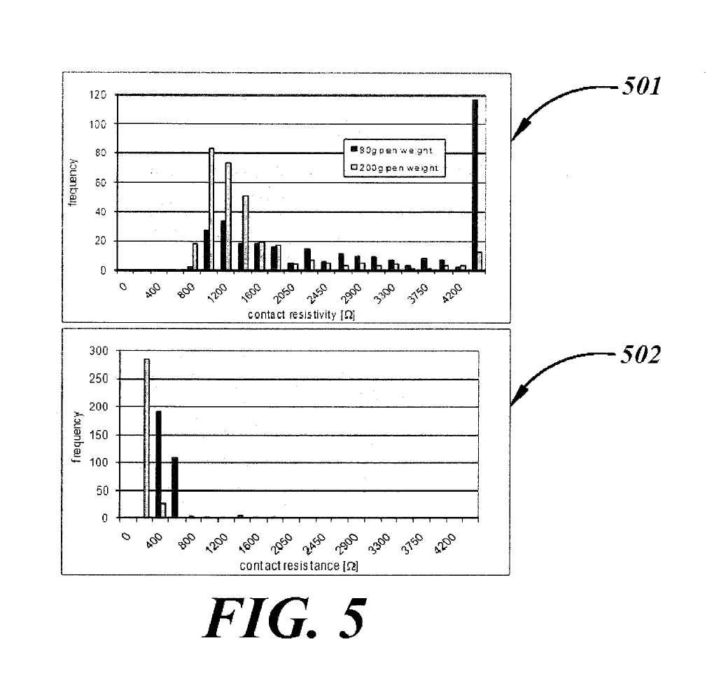

As seen in FIG. 5, when the data from the plots 401 and 402 are statistically sampled, there are generated two distributions 501 and 502. As seen in the distribution 501, the distribution of contact resistances from plot 401 is highly variable and largely spread across many different values. The distribution 502 determined from the contact resistances of plot 402, on the other hand, has a much less variable distribution of contact resistances, with most of the contact resistances concentrated toward lower values. From the distributions 501 and 502, it is possible to develop a set of criteria for determining when a touch panel undergoing testing will function within acceptable limits.

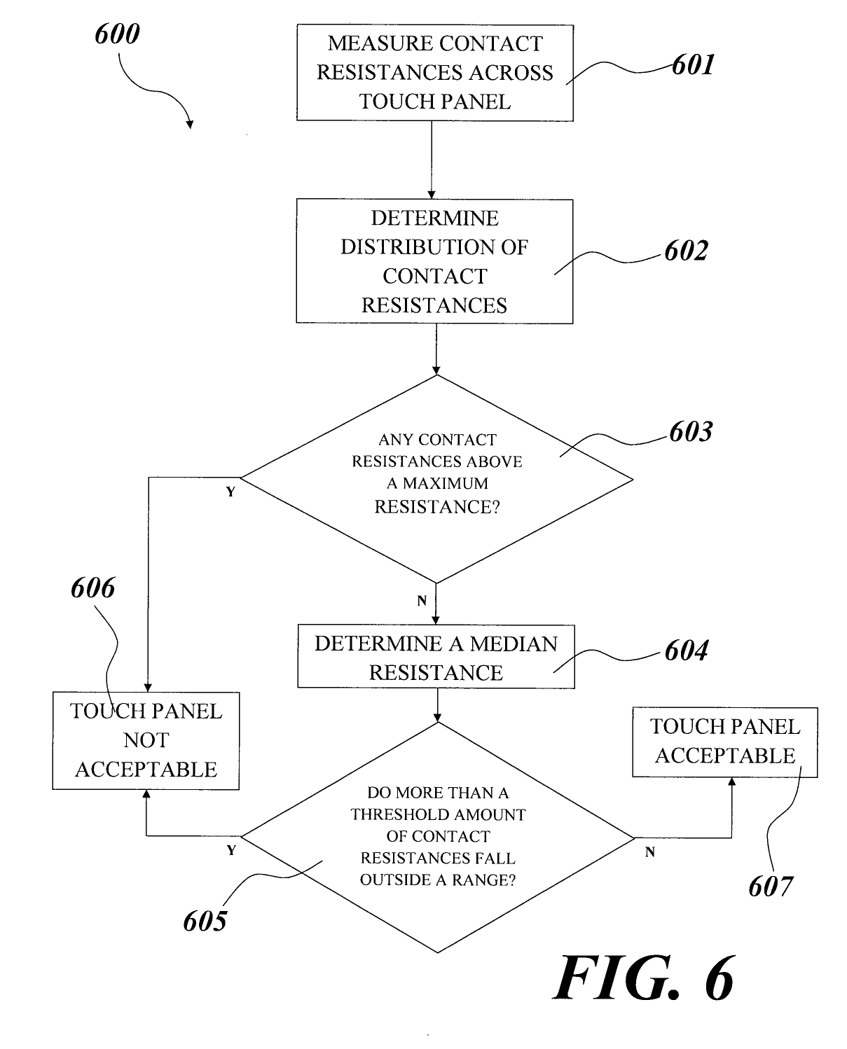

FIG. 6 illustrates a process 600 according to one embodiment by which a touch panel may be tested to determine if it operates within acceptable limits. As previously discussed, a set of three stripes (see FIG. 3) may be drawn across the surface of a touch panel at which point sensing voltages are concurrently measured at step 601 and converted to contact resistances. The contact resistances may be converted as each sensing voltage is measured, or after all sensing voltages are measured and stored. This set of sensing voltages is converted into a set of contact resistances using the resistance conversion equation above, after which the set of contact resistances are stored in a memory. Based on the converted contact resistances, a distribution of contact resistances is determined at step 602 using well known statistical analysis.

According to one embodiment, after the distribution of contact resistances is determined at step 602, if any of the contact resistances is above a maximum resistance threshold, as determined in step 603, then the touch panel is determined to be unusable at step 606. When a contact resistance of a touch panel is high, a corresponding larger sensing voltage will have been measured. As a result of the high contact resistance and sensing voltage, it is difficult to determine location coordinates on the touch panel and thus output an accurate point reflecting where a user or pen has touched the screen. While there may be some variability among contact resistances across the touch panel, it is desirable to have no contact resistances that are higher than a threshold limit.

According to another embodiment, if none of the contact resistances from the set of converted contact resistances is above the maximum resistance threshold as determined in step 603, or there is no such determination made or required, a median of the set of contact resistances is determined at step 604. In one embodiment, at step 605, the set of contact resistances is analyzed to determine how many contact resistances fall outside a range of contact resistances. The range of contact resistances preferably has the median contact resistance at its center, and is preferably relatively narrow, as will be described later. If the number of contact resistances falling outside the range is greater than a given threshold, the touch panel is determined to be unusable at step 606. If the number of contact resistances falling outside the range is less than or equal to the given threshold, however, then the touch panel is determined to operable within acceptable limits at step 607.

According to a preferred embodiment, the median value of contact resistances from the set of contact resistances is below 1.6 kΩ based on a V₀ of 5V, an R_{T} of 100 kΩ, and V_{S} between 50 mV and 60 mV. Similarly, the maximum resistance threshold at step 603 is preferably set at 1.0 kΩ higher than the median contact resistance. It should be appreciated that the exact value of the reference resistance R_{T} and other values is less important than is the order of magnitude of the contact resistances and sheet resistances compared with the reference resistor R_{T} and an overall input impedance of the touch panel R_{D} to determine usability of a touch panel.

According to a preferred embodiment, the limits and thresholds are determined on a ratio-basis corresponding to an overall input impedance R_{D} of external circuitry to which the touch panel is connected. Thus, it is desirable for the contact resistances and the sheet resistances to be much smaller in magnitude than the input impedance R_{D} for the touch panel to operate within acceptable limits. In the present embodiment, an input impedance R_{D} of 1 MΩ is used. However, it will be appreciated that if a different input impedance R_{D} is used, then the values that determine whether or not a touch panel operates within acceptable limits will scale accordingly.

According to the present embodiment, the median contact resistance is no more than 1.6 kΩ, or 0.16% of the input impedance R_{D}. Additionally, the maximum resistance threshold may be up to 0.1% of the input impedance R_{D} more than the median contact resistance. Alternatively, the maximum resistance threshold may be between 0.05% of the input impedance R_{D} and 0.15% of the input impedance R_{D}. According to the embodiment at step 605, at least 80% of the contact resistances calculated from the measured set of sensing voltages falls within a range of acceptable contact resistances. Preferably, the range is between 400Ω less than and 400Ω more than the median value of the contact resistances.

In another embodiment, the range of contact resistances may be determined as a percentage below or above the input impedance R_{D}. For example, it is preferred that the range of contact resistances have an upper limit not larger than approximately 0.04% of the input impedance R_{D} above the median contact resistance and have a lower limit not smaller than approximately 0.04% of the input impedance R_{D} lower than the median contact resistance. In an alternative embodiment, the upper limit may be no more than 0.05% of the input impedance R_{D} and the lower limit may be no less than 0.02% of the input impedance R_{D}.

It should also be appreciated, however, that since contact resistances smaller than the median contact resistance are more ideal as they approach zero, the lower limit may be lower, for example, 0.02% of the input impedance R_{D}, or there may not even be a lower range on the range of contact resistances. It should also be appreciated that any distribution around the median value of contact resistances that provides stable tracking of input to output, and reasonably eliminates any such failures is contemplated within the scope of the present disclosure, regardless of the exact values used.

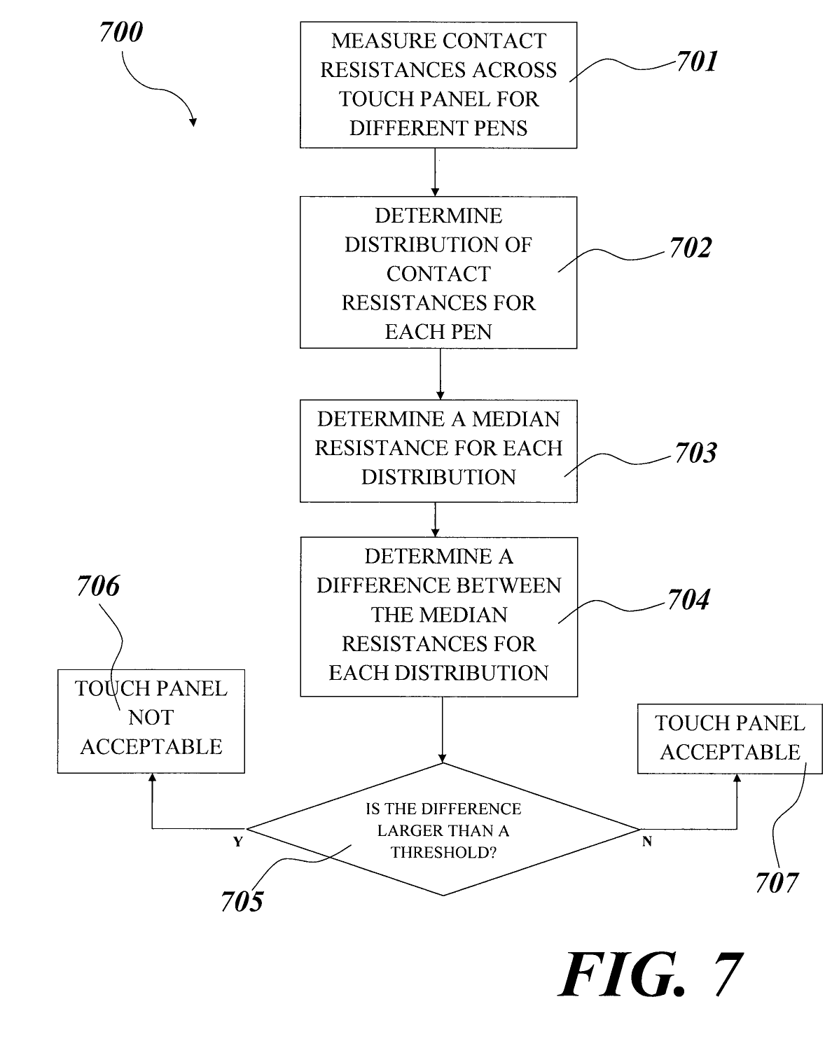

In an another embodiment, as shown in the process 700 of FIG. 7, two tests may be performed on the same touch panel using two different pens with different pen weights. As with the process 600 of FIG. 6, each pen is used to draw three test stripes corresponding to the stripes 301, 302, and 303 as described with regard to FIG. 3, or any other suitable test pattern. Two sets of sensing voltages are measured corresponding to the respective pens and converted into two sets of contact resistances as shown in step 701. In step 702, two distributions are determined for each set of contact resistances similar to the determined distributions at step 602 of FIG. 6. And in step 703, the median contact resistance for each distribution is calculated as was done in step 604 of FIG. 6. At step 704, the difference between the two determined median contact resistances is calculated. At step 705, if the difference between the median contact resistances is greater or equal to a resistance threshold, then the touch panel is determined to not be operable within acceptable ranges as determined in step 706; otherwise the touch panel is operable in acceptable ranges as determined in step 707.

According to one embodiment, the resistance threshold is 400Ω. However, the resistance threshold may be any suitable threshold, for example, if the differences between the two median contact resistances for each pen is within 0.04% of the input impedance R_{D}, then the touch panel may be determined to be operable within acceptable limits. Otherwise, if the two median contact resistances vary larger than 400Ω or 0.04% of the input impedance R_{D}, then the variability of contact resistances for the touch panel is too great and will likely result in undesirable functionality.

According to this embodiment, using different pen weights ideally has little effect on sensing voltage, and thus has little effect on the contact resistance for the touch panel. If, however, there is a large enough difference between the median contact resistances for each pen, then inaccurate position information will result and the output on the touch panel will not track the input. In this embodiment, the pen weights correspond to 80 grams and 200 grams; however, any pens or devices of suitable weight may be used.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A transparent conductor for use in a touch panel, the transparent conductor comprising:
a substrate; and
a conductive layer on the substrate, the conductive layer including a plurality of conductive nanostructures and having a range of contact resistances that is between a lower value and an upper value, the median contact resistance being less than a limit resistance at which the conductive layer begins to have degraded performance.

2. The transparent conductor of claim 1, the upper value being 0.16% of an input impedance of the touch panel.

3. The transparent conductor of claim 1, the limit resistance being 0.1% of an input impedance of the touch panel above the median contact resistance.

4. The transparent conductor of claim 1, the limit resistance being between 0.05% and 0.15% of an input impedance of the touch panel.

5. The transparent conductor of claim 1, the conductive layer having a sheet resistance that is linear across the conductive layer.

6. A touch panel comprising:
a substrate; and
a conductive layer on the substrate, the conductive layer including a plurality of conductive nanostructures, the conductive layer having contact resistances, wherein most of the contact resistances fall between a lower percentage of an input impedance of the touch panel that is below a first median contact resistance and an upper percentage of the input impedance of the touch panel that is above the first median contact resistance.

7. The touch panel of claim 6, further comprising:
a second median contact resistance, the first median contact resistance of the conductive layer being associated with contact resistances produced by a first pen, and the second median contact resistance of the conducive layer being associated with contact resistances produced by a second pen, wherein a difference between the first median contact resistance and the second median contact resistance is no greater than a threshold difference.

8. The touch panel of claim 7, the threshold difference corresponding to no more than a 0.04% of the input impedance of the touch panel.

9. The touch panel of claim 6, wherein most of contact resistances comprises 80% of the contact resistances.

10. The touch panel of claim 6, wherein the lower percentage of the input impedance of the touch panel is 0.08% and the upper percentage of the input impedance of the touch panel is 0.16%.

11. A method comprising:
measuring a set of contact resistances across a surface of a transparent conductor of a touch panel;
determining a median contact resistance from the set of contact resistances;
determining a percentage of the contact resistances from the set of contact resistances that fall within a range of resistances that surrounds the median contact resistance; and
determining when either the percentage of the contact resistances is lower than a first percentage threshold, or a contact resistance from the set of contact resistances is above a contact resistance limit.

12. The method of claim 11, the range of resistances comprises at least 80% of the contact resistances from the set of contact resistances.

13. The method of claim 11, the range of resistances having a distribution between 0.04% of an input impedance of a touch panel below the median contact resistance and 0.04% of the input impedance above the median contact resistance.
